(19) United States
(12) Patent Application Publication
(10) Pub. No.: US 2009/0129019 A1
(43) Pub. Date: May 21, 2009

(54) HEAT DISSIPATION DEVICE WITH FAN HOLDER

(75) Inventors: MIN LI, Shenzhen (CN); LEI CAO, Shenzhen (CN)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/940,943

(22) Filed: Nov. 15, 2007

(51) Int. Cl. H05K 7/20

(52) U.S. Cl. 361/697

(57) ABSTRACT

A heat dissipation device includes a heat sink attached to an electronic component, a fan and a fan holder mounting the fan onto the heat sink. The heat sink includes a plurality of fins. The fan holder includes a plurality of walls connecting with each other. A pair of tabs is formed on one of the walls for abutting against the fan, and a pair of fasteners is formed on another wall and opposite to the tabs. Each of the fasteners includes a sleeve formed on the another wall, a pressing member movably received in the sleeve, and a crank pivotally engaged with the sleeve. When the crank is positioned in a closed position, the pressing member is pushed out of the sleeve by the crank and abuts against the fan. The fasteners cooperate with the tabs to mount the fan onto the fan holder.

### BACKGROUND OF THE INVENTION

1. Field of the Invention

The present invention relates generally to a heat dissipation device, and more particularly to a heat dissipation device having a fan holder for mounting a fan onto a heat sink of the heat dissipation device, wherein the fan can be easily assembled to and disassembled from the fan holder.

2. Description of related art

It is well known that during operation computer electronic devices such as central processing units (CPUs) can generate large amounts of heat. The heat must be quickly removed from the electronic device to prevent it from becoming unstable or being damaged. Typically, a heat sink is attached to an outer surface of the electronic device to absorb heat from the electronic device, and the heat absorbed by the heat sink is then dissipated to ambient air.

Generally, in order to improve heat dissipation efficiency of a heat sink, a fan is desired to direct airflow onto the heat sink. It is generally to fix the fan onto the heat sink with screws. Furthermore, it is necessary to disassemble the fan from the heat sink when dust particles accumulate in the fan and the heat sink, whereby the fan and the heat sink can be cleaned. Otherwise, heat dissipation efficiency of the heat sink will be decreased and a lifespan of the fan will be shortened. After cleaning of the fan and heat sink, it is required to assemble the fan to the heat sink again. Both the disassembling and assembling require to rotate the screws by using a screwdriver. Such an unscrewing and screwing operation is laborious and time consuming. In addition, it is possible that the screws or screwdriver may drop to cause damages to computer components in the process of assembling and disassembling.

What is needed, therefore, is a heat dissipation device which has a fan holder for mounting a fan onto a heat sink wherein the fan can be easily assembled to and disassembled from the fan holder without a tool.

### SUMMARY OF THE INVENTION

A heat dissipation device includes a heat sink attached to an electronic component, a fan and a fan holder mounting the fan onto the heat sink. The heat sink includes a plurality of fins. The fan holder includes a plurality of walls connecting with each other, a pair of tabs formed on one of the walls for abutting against the fan, and a pair of fasteners formed on another wall and opposite to the tabs. Each of the fasteners includes a sleeve formed on the another wall, a pressing member received in the sleeve, and a crank pivotally engaged with the sleeve. When the crank is positioned in a closed position, the pressing member is pushed out of the sleeve by the crank and abuts against the fan, whereby the pressing member cooperates with the tabs to mount the fan onto the fan holder.

Other advantages and novel features will become more apparent from the following detailed description of preferred embodiments when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is an exploded, isometric view of a heat dissipation device in accordance with a preferred embodiment of the present invention;

FIG. 2 is a partly assembled view of FIG. 1, wherein a fan holder is attached to a heat sink;

FIG. 3 is an assembled view of FIG. 1, with part of a sleeve thereof cut away for clarity and a crank of the fan holder in an opened position; and

FIG. 4 is an assembled view of FIG. 1, with part of the sleeve thereof cut away for clarity and the crank of the fan holder in a locked position.

### DETAILED DESCRIPTION OF THE INVENTION

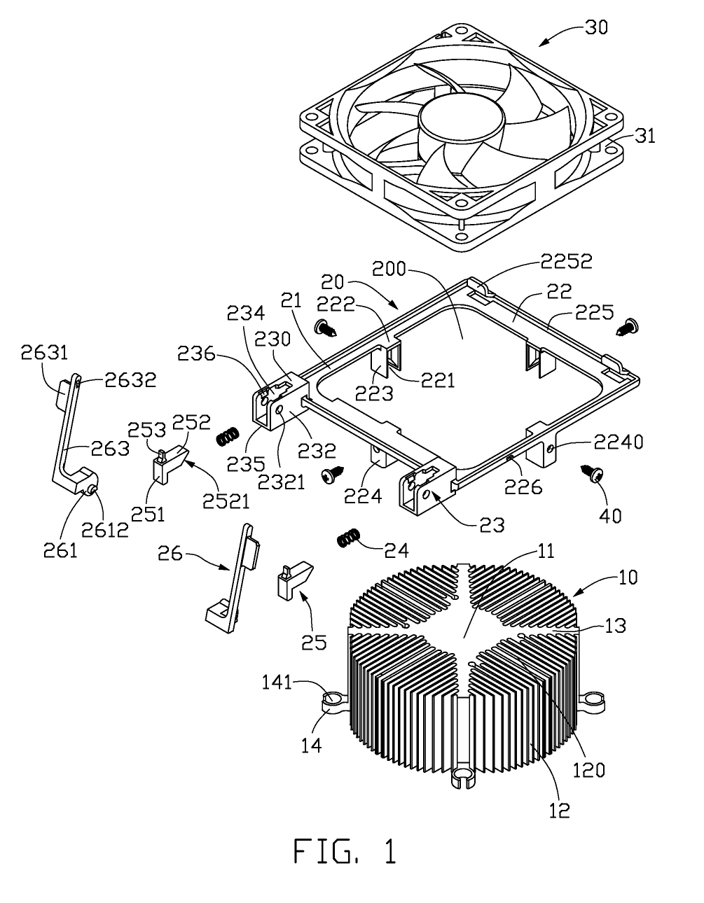

Referring to FIG. 1, a heat dissipation device is disclosed for dissipating heat generated by an electronic component (not shown) mounted on a printed circuit board (not shown). The heat dissipation device comprises a heat sink 10 attached to the electronic component, a fan holder 20 and a fan 30. The fan 30 is mounted to the heat sink 10 via the fan holder 20.

The heat sink 10 comprises a cylinder core 11 and four symmetrical branches 13 extending outwardly from the core 11. A plurality of fins 12 projects outwardly from outer side surfaces of the core 11 and the branches 13. The fins 12 have a circumferential outer surface, which is so configured that the heat sink 10 has a cylindrical configuration. The fins 12 can be divided into four groups oriented at four different directions. Four side surfaces of the core 11 and the four branches 13 form four regions. Each group of the fins 12 is formed at a corresponding region. Two neighboring groups of the fins 12 are oriented perpendicularly to each other. A pair of adjoining mounting fins 120 each of which is thicker than other fins 12 are formed on a center of each group of the fins 12. Four ears 14 are symmetrically formed at bottom portions of the branches 13. Each ear 14 has a through hole 141 defined therein for providing a passage of a corresponding screw (not shown) to mount the heat sink 10 on the printed circuit board.

The fan holder 20 is attached to the heat sink 10 and comprises two pairs of walls 21,22 connecting with each other to construct a rectangular configuration thereof. A central opening 200 is enclosed by the walls 21, 22 for allowing passage of airflow generated by the fan 30 towards the heat sink 10. Each wall 21, 22 forms a mounting portion (not labeled) thereon. Each mounting portion comprises a top plate 222 extending inwardly and horizontally from a center of the corresponding wall 21, 22, two parallel lateral baffle-plates 223 extending perpendicularly and downwardly from opposite edges of the top plate 222 and a mounting plate 224 extending perpendicularly and downwardly from an end of the top plate 222 and connecting the baffle-plates 223 in a manner such that a cavity 221 is defined among the top plate 222, the baffle-plates 223 and the mounting plate 224. A screw hole 2240 is defined in the mounting plate 224. The mounting fins 120 of each group of fins 12 of the heat sink 10 are received in the corresponding cavity 221 of each wall 21, 22. Top portions of the mounting fins 120 abut against the corresponding top plate 222 and outer surfaces of the mounting fins 120 abut against inner surfaces of the corresponding lateral baffle-plates 223 such that the top plate 222 and the baffle-plates 223 can clasp the mounting fins 120 therebetween for preventing the mounting fins 120 from being deformed outwardly during screwing of a self-tapping screw 40 into a space between the mounting fins 120 through a corresponding screw hole 2240.

Each wall 21, 22 has an abutting strip 225 extending upwardly from an outer edge thereof. A pair of tabs 2252 extend upwardly and inwardly from opposite ends of the abutting strip 225 of a rear one of the walls 22. A pair of protrusions 226 are formed at opposite outer sides of the walls 21, respectively.

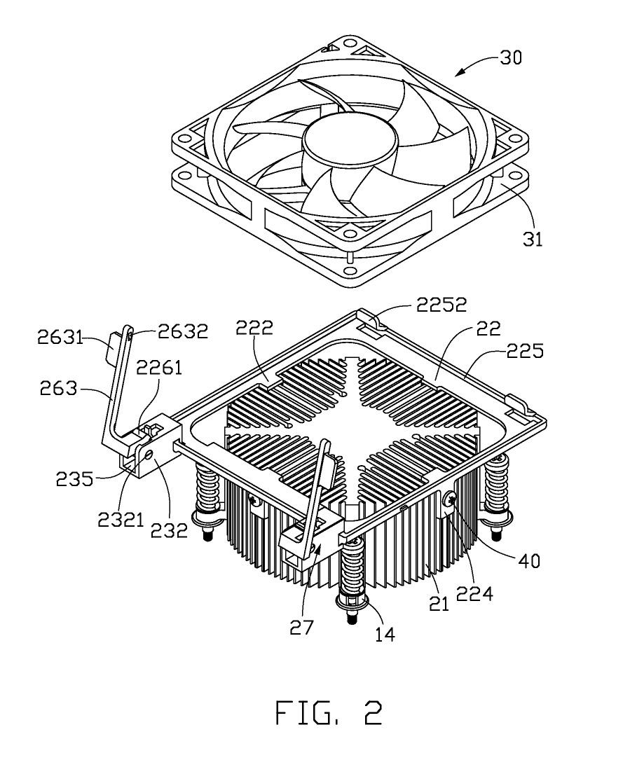

A pair of fasteners 27 (shown from FIG. 2) are formed at opposite ends of a front one of the walls 22, opposing to the tabs 2252. The fasteners 27 and the tabs 2252 cooperatively fasten the fan 30 onto the fan holder 20. Each fastener 27 comprises a sleeve 23 extending outwardly from the front one of the walls 22, a spring 24 and a pressing member 25 received in the sleeve 23, and a crank 26 pivotally engaged with the sleeve 23.

The sleeve 23 of each fastener 27 has a hollow cube-like configuration. The sleeve 23 comprises a top plate 230, a pair of parallel sidewalls 232 extending downwardly from two opposite lateral sides of the top plate 230 and a bottom plate 235 opposite to the top plate 230 and extending outwardly from a bottom of the abutting strip 225. The top plate 230 defines a cutout (not labeled). The sidewalls 232 connect with the abutting strip 225 and define a pair of opposite mounting holes 2321. The sleeve 23 defines a through hole 234 extending along a front-to-rear direction thereof. The through hole 234 is enclosed by the top plate 230, the bottom plate 235 and the pair of sidewalls 232. The through hole 234 communicats with the cutout of the top plate 230 for receiving the spring 24, the pressing member 25 and the crank 26 therein. A guiding recess 236 is defined at a top of each sidewall 232 and located above the mounting hole 2321.

Each pressing member 25 has an L-shaped configuration and comprises a vertical supporting portion 251 and a pressing portion 252 extending perpendicularly from a top free end of the supporting portion 251. A bar 253 extends upwardly from a end of the pressing portion 252, adjacent to the supporting portion 251. The pressing portion 252 has a top surface and a bottom surface opposite to the top surface. The top surface of the pressing portion 252 has a length longer than that of the bottom surface of the pressing portion 252. A slope 2521 is formed at a rear end of the pressing portion 251 and connects with a rear end of the top surface and a rear end of the bottom surface of the pressing portion 252. The pressing member 25 is received in the through hole 234 of the sleeve 23. The spring 24 is received in the though hole 234 and sandwiched between the abutting strip 225 of the front one of the walls 22 and a rear surface of the supporting portion 251 of the pressing member 25.

Each crank 26 comprises a cam portion 261 and an operating portion 263 extending from an end of the cam portion 261. The cam portion 261 forms a pair of pivots 2621 at opposite sides thereof, corresponding to the mounting holes 2321 of the sleeve 23. The operating portion 263 is an elongated strip extending perpendicularly from a free end of the pivot portion 261. A handle 2631 extends perpendicularly and outwardly from a side of the operating portion 263, for facilitating an operation of the crank 26. A recess 2632 is defined in a lateral surface of the operating portion 263, corresponding to the protrusion 226 of the wall 21.

The fan 30 has a rectangular configuration and comprises a top plate (not labeled) and a bottom plate 31.

Referring to the FIG. 2, in assembly, the fan holder 20 is attached on the heat sink 10. The self-tapping screws 40 extend through the mounting holes 2240 of the mounting portion of the fan holder 20 into the spaces between the mounting fins 120 and threadedly engage with them by self-tapping thereby securely mounting the fan holder 20 onto the heat sink 10. The spring 24 and the pressing member 25 are received in the through hole 234 of each sleeve 23 of the fan holder 20. Then the pivots 2612 of the cam portion 261 are engaged in the mounting holes 2321 of the sleeve 23 by a guiding of the guiding recess 236 of the sleeve 23, thus the crank 26 is assembled to the sleeve 23.

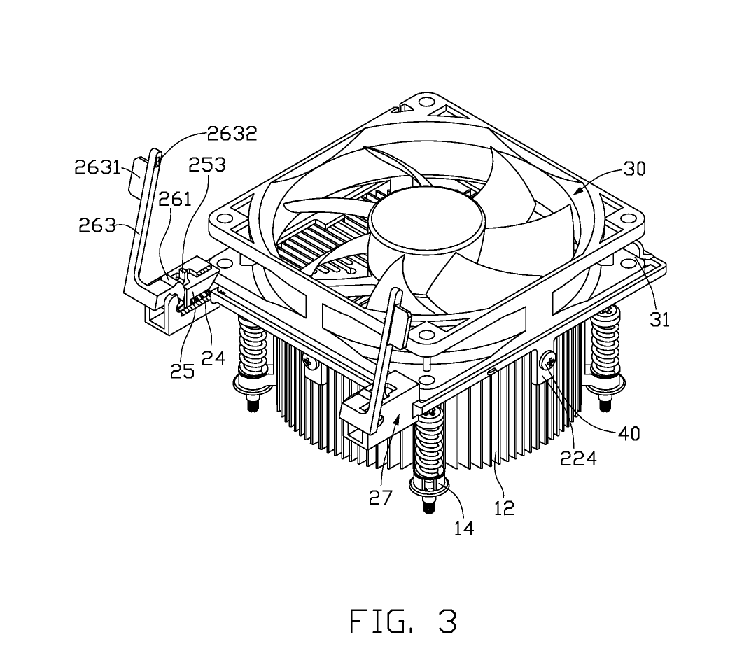

Referring to the FIG. 3, the fan 30 is placed into a space defined by the walls 21, 22. The tabs 2252 abut against the bottom plate 31 of the fan 30. In this original position, the crank 26 is positioned in an opened position. The operating portion 263 of the crank 26 is oriented nearly upright. The handle 2631 is located above the top plate of the fan 30. The slope 2521 of the pressing portion 252 of the pressing member 25 is located near to the bottom plate 31 of the fan 30, but not contacts with it.

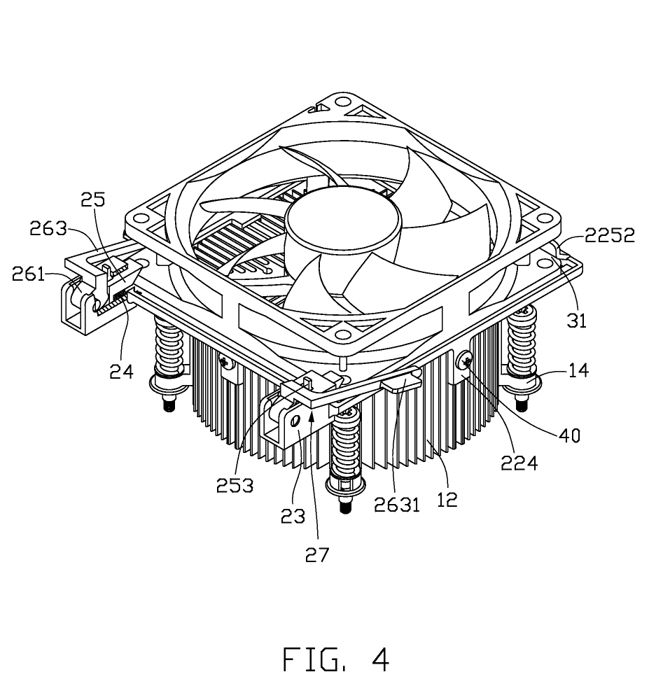

Referring to FIG. 4, the handle 2631 of the operating portion 263 of the crank 26 is pressed downwardly; the cam portion 261 is rotated about 90 degrees about the pivot 2612 in a clockwise direction; thus, the pressing member 25 is pushed by the operating portion 263 of the crank 26 forward until the bar 253 abuts against the top plate 230 of the sleeve 23 and the protrusion 226 of the wall 21 is engaged in the recess 2632 of the crank 26. In this state, the crank 26 is positioned in a closed position.

Particularly referring to FIGS. 3-4, the operating portion 263 of the crank 26 is pressed from the opened position to the closed position. In this closed position, the operating portion 263 is nearly horizontal. The pressing member 25 is pushed by the cam portion 261 of the crank 26 to move through the through hole 234 to a position beyond the rear end of the sleeve 23, whereby the slope 2521 of the pressing portion 251 of the pressing member 25 presses the corresponding bottom plate 31 of the fan 30. Due to a forward movement of the pressing member 25, the spring 24 is compressed between the abutting strip 225 of the front one of the walls 22 and the supporting portion 251 of the pressing member 25. Thus, the fan 30 is fixedly mounted on the fan holder 20. When the fan 30 is needed to be disassembled from the heat sink 10, the engagement between the protrusions 226 and the recesses 2632 is released by moving the operating portions 263 of the cranks 26 outwardly. As soon as the engagement is released, a force is then applied on the rear surface of the supporting portion 251 of the pressing member 25 by the spring 24 to make the slope 2521 of the pressing portion 252 of the pressing member 25 away from the bottom plate 31 of the fan 30. Then, the fan 30 is pulled out from the tabs 2252 of the rear one of the walls 22; thus, the fan 30 is detached from the heat sink 10.

By provision of the fasteners 27 and the tabs 2252, the fan 30 can be easily assembled to and disassembled from the fan holder 20 via operating the operating portions 263 of the fasteners 27.

It is believed that the present embodiments and their advantages will be understood from the foregoing description, and it will be apparent that various changes may be made thereto without departing from the spirit and scope of the invention or sacrificing all of its material advantages, the examples hereto described merely being preferred or exemplary embodiments of the invention.

What is claimed is:

1. A heat dissipation device adapted for dissipating heat generated by an electronic component mounted on a printed circuit board, comprising:
a heat sink attached to the electronic component, comprising a plurality of fins;
a fan; and
a fan holder mounting the fan onto the heat sink, the fan holder comprising
a plurality of walls connecting with each other, a pair of tabs formed on one of the walls for abutting against the fan, and a pair of fasteners formed on another wall and opposite to the tabs, and each of the fasteners comprising a sleeve formed on the another wall, a pressing member received in the sleeve, and a crank pivotally engaged with the sleeve, wherein when the crank is positioned in a closed position, the pressing member is pushed out of the sleeve by the crank and abuts against the fan, the pressing members cooperating with the tabs to mount the fan onto the fan holder.

2. The heat dissipation device of claim 1, wherein the crank comprises a cam portion pivotally engaged with the sleeve and an operating portion extending from an end of the cam portion, the operating portion being operated to make the cam portion rotate to push the pressing member towards the fan.

3. The heat dissipation device of claim 2, wherein the operation portion of the crank defines a recess therein, and one of the wall forms a protrusion received in the recess of the crank when the crank is positioned in the closed position.

4. The heat dissipation device of claim 2, wherein the operating portion extends a handle for facilitating operation of the crank.

5. The heat dissipation device of claim 1, wherein the sleeve of the fan holder has a hollow cube-shaped configuration for receiving the pressing member and the crank.

6. The heat dissipation device of claim 5, wherein the sleeve of the fan holder comprises a top plate, a pair of parallel sidewalls extending from opposite lateral sides of the top plate and connecting with the another wall and a bottom plate opposite to the top plate and the top plate, the sidewalls and the bottom plate form a cavity to receive the pressing member and the crank therein.

7. The heat dissipation device of claim 1, wherein the pressing member has an L-shaped configuration and comprises a supporting portion contacting the sleeve and a pressing portion extending outwardly from the supporting portion to press the fan.

8. The heat dissipation device of claim 7, wherein a bar is formed at an end of the pressing portion of the pressing member adjacent to supporting portion, when the crank is positioned at the closed position, the bar abutting against the top plate of the sleeve defining a cutout therein.

9. The heat dissipation device of claim 8, wherein the pressing member has a top surface, a bottom surface opposite to the top surface, and a slope connecting with an end of the top surface and an end of the bottom surface, the top surface having a length longer than that of the bottom surface.

10. The heat dissipation device of claim 1, wherein each of the one of the walls and the another walls has an abutting strip extending upwardly from an outer edge thereof and the pair of tabs extend upwardly and inwardly from the abutting strip of the one of the walls and the bottom plate of the sleeve extends outwardly from a bottom of the abutting strip opposite to the tabs.

11. The heat dissipation device of claim 7 further comprising a spring sandwiched between the another wall and the supporting portion of the pressing member.

12. The heat dissipation device of claim 1, wherein each of the walls forms a mounting portion engaged with the fins of the heat sink to mount the fan holder to the heat sink.

13. The heat dissipation device of claim 1, wherein the mounting portion comprises a top plate extending inwardly from a corresponding wall, a pair of baffle-plates extending downwardly from opposite edges of the top plate and a mounting plate extending downwardly from an end of the top plate and connecting with the baffle-plates.

14. The heat dissipation device of claim 13, wherein the fins of the heat sink are divided into a plurality of groups, a pair of adjoining mounting fins each of which is thicker than other fins formed on each group of the fins being received in the mounting portion of the fan holder, a self-tapping screw extending through the mounting plate of the mounting portion of the fan holder into a space between the two mounting fins and threadedly engaging with the two mounting fins by self-tapping, thereby mounting the fan holder onto the heat sink.

15. The heat dissipation device of claim I, wherein the fins of the heat sink are divided into four groups oriented at four different directions and two neighboring groups of the fins are oriented perpendicularly to each other.

16. A heat dissipation device comprising:
a heat sink having a core with a bottom face adapted for contacting with a heat-generating electronic component, and a plurality of fins extending radially outwardly from the core;
a fan holder attached on the heat sink, comprising a plurality of mounting plates engaging with the fins, a plurality of tabs and a plurality of fasteners located opposite the tabs, each fastener comprising a sleeve, a pressing member movably received in the sleeve, a crank pivotably mounted to the sleeve and a spring received in the sleeve; and
a fan mounted on the fan holder by engaging with the tabs and the fasteners, wherein when the crank is moved to a substantially horizontal orientation, the pressing member is pushed by the crank to have a portion thereof moved out of the sleeve and pressing the fan toward the heat sink and the spring is compressed between the fan holder and the pressing member.
